(19) United States
(12) Patent Application Publication
(10) Pub. No.: US 2025/0289834 A1
(43) Pub. Date: Sep. 18, 2025

(54) SILICON COMPOUND AND METHOD OF PRODUCING SILICON-CONTAINING THIN FILM USING THE SAME

(71) Applicant: DNF CO., LTD., Daejeon (KR)

(72) Inventors: Se Jin JANG, Daejeon (KR); Sung Gi KIM, Daejeon (KR); In Kyung JUNG, Daejeon (KR); Jeong Joo PARK, Daejeon (KR); Samdong LEE, Daejeon (KR); Jun Hee CHO, Daejeon (KR); Gun Joo PARK, Daejeon (KR)

(21) Appl. No.: 19/078,327

(22) Filed: Mar. 13, 2025

(30) Foreign Application Priority Data
Mar. 14, 2024 (KR) 10-2024-0035756

(51) Int. Cl. C07F 7/10; C01B 33/12; C23C 16/40; C23C 16/455

(52) U.S. Cl. CPC C07F 7/10; C01B 33/12; C23C 16/401; C23C 16/45553; C01P 2002/54

(57) ABSTRACT

Provided are a silicon compound, a composition for depositing a silicon-containing thin film including the silicon compound, and a method of producing a silicon-containing thin film using the silicon composition. Since the silicon-containing thin film produced using the silicon compound as a silicon precursor has both excellent chemical and thermal stability and has a low dielectric constant, it may be usefully applied as an insulating film of a semiconductor device, in particular, a spacer of a semiconductor miniaturization process.

### CROSS-REFERENCE TO RELATED APPLICATIONS

This application claims priority under 35 U.S.C. § 119 to Korean Patent Application No. 10-2024-0035756, filed on Mar. 14, 2024, the disclosure of which is incorporated herein by reference in its entirety.

### TECHNICAL FIELD

The following disclosure relates to a silicon compound used as a precursor of a silicon-containing thin film, a composition for depositing a silicon-containing thin film including the same, and a method of producing a silicon-containing thin film using the same.

### BACKGROUND

A silicon thin film produced by various deposition methods such as atomic layer deposition (ALD) and chemical vapor deposition (CVD) is being used as a semiconductor substrate, a diffusion mask, an anti-oxidation film and a dielectric film, an insulating film, and the like in semiconductor technology.

Meanwhile, it is important for an insulating film for a spacer of a semiconductor device to have a low-dielectric constant and excellent corrosion resistance, and furthermore, in order to apply it to an actual process, conditions such as ease of process and excellent chemical and thermal stability should be satisfied, and thus, the physical properties required for the insulating film for a spacer which is applied to a next-generation semiconductor device are gradually advanced.

To this end, studies for lowering the dielectric constant of the silicon thin film continue, but a sufficiently low dielectric constant is not secured or thermal stability and corrosion resistance are reduced, and productivity decreases due to a low thin film formation rate. In addition, as a method of satisfying both the low dielectric constant and corrosion resistance of the silicon thin film, a method of doping fluorine (F) after forming a silicon-containing thin film has been suggested. However, the method further involves a fluorine doping step which makes the process complicated, the doping proceeds mainly only near the surface of the thin film, making it difficult to perform F doping in an area deeper than the surface, and thus, the quality of the thin film is deteriorated.

### RELATED ART DOCUMENTS

### Patent Document

(Document 1) JP 19960236521

### SUMMARY

An embodiment of the present invention is directed to providing a silicon compound which is a high-quality low-dielectric thin film precursor and a method of producing the same.

Another embodiment of the present invention is directed to providing a method of producing a silicon-containing thin film, which allows deposition of a thin film with a high thin film deposition rate even under mild conditions and production of a high-quality thin film with a high yield.

In one general aspect, a silicon compound represented by the following Chemical Formula 1 is provided:

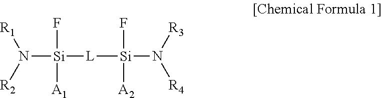

wherein

A₁ and A₂ are independently of each other hydrogen, fluoro, C1-C7 alkyl, or —N (R₁₁) (R₁₂);

L is C1-C7 alkylene; and

R₁ to R₄, R₁₁, and R₁₂ are independently of one another C1-C7 alkyl.

A₁ and A₂ may be independently of each other hydrogen, fluoro, C1-C4 alkyl, or N (R₁₁) (R₁₂); L may be C1-C4 alkylene; and R₁ to R₄, R₁₁, and R₁₂ may be independently of one another C1-C4 alkyl.

The silicon compound according to an exemplary embodiment may be represented by the following Chemical Formula 1-1 or Chemical Formula 1-2:

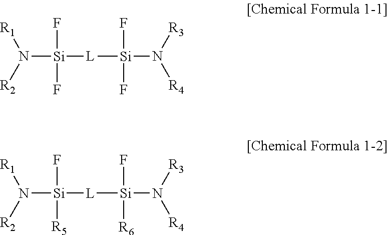

wherein

L is C1-C7 alkylene;

R₁ to R₄ are independently of one another C1-C7 alkyl;

R₅ and R₆ are independently of each other hydrogen, C1-C7 alkyl, or —N (R₁₁) (R₁₂); and

R₁₁ and R₁₂ are independently of each other C1-C7 alkyl.

L may be C1-C4 alkylene; R₁ to R₄ may be independently of each other C1-C4 alkyl; R₅ and R₆ may be independently of each other C1-C4 alkyl or —N (R₁₁) (R₁₂); and R₁₁ and R₁₂ may be independently of each other C1-C4 alkyl.

The silicon compound according to an exemplary embodiment may be selected from the following structures:

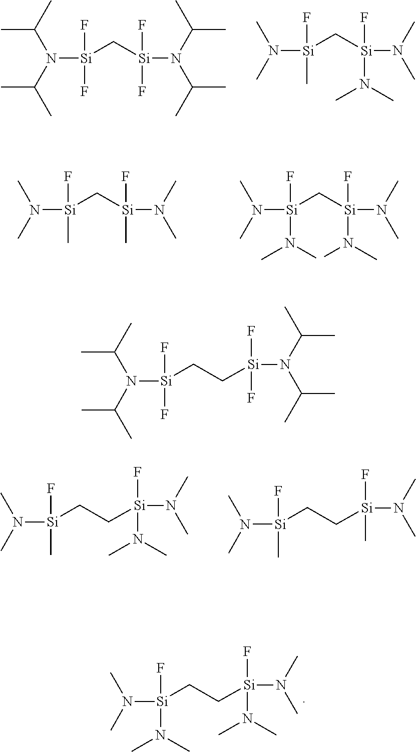

In another general aspect, a method of producing a silicon compound includes: reacting a compound of the following Chemical formula 2 with compounds of the following Chemical Formulae 11 and 12 to produce a compound of the following Chemical Formula 3; and reacting the compound of Chemical Formula 3 with a fluorine source to produce a silicon compound of the following Chemical Formula 1-1:

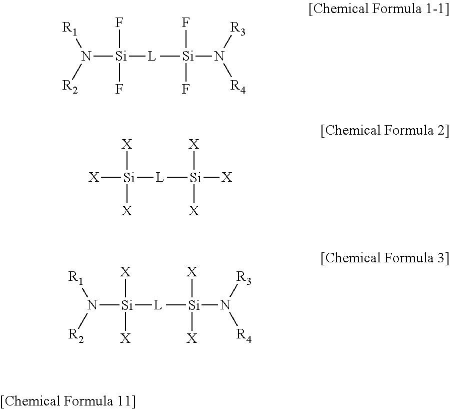

(R₁) (R₂) NH

[Chemical Formula 12]

(R₃) (R₄) NH

wherein

X is Cl or Br; and

R₁ to R₄ are independently of one another C1-C7 alkyl.

In another general aspect, a method of producing a silicon compound includes: reacting a compound of the following Chemical Formula 2 with a fluorine source to produce a compound of the following Chemical Formula 4; and reacting the compound of the following Chemical Formula 4 with compounds of the following Chemical Formulae 11 and 12 to produce a silicon compound of the following Chemical Formula 1-1:

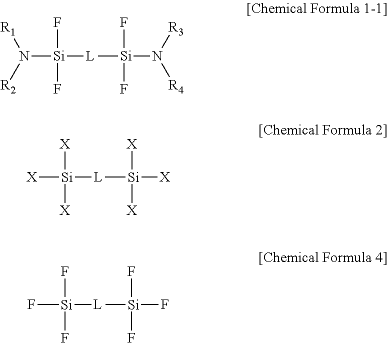

[Chemical Formula 11]

(R₁) (R₂) NH

[Chemical Formula 12]

(R₃) (R₄) NH

wherein

X is Cl or Br; and

R₁ to R₄ are independently of one another C1-C7 alkyl.

In another general aspect, a composition for depositing a silicon-containing thin film includes the silicon compound.

In still another general aspect, a method of producing a silicon-containing thin film using the silicon compound or the composition for depositing a silicon-containing thin film including the compound is provided.

The silicon-containing thin film according to an exemplary embodiment may be a fluorine and silicon-containing thin film.

The silicon-containing thin film according to an exemplary embodiment may contain 0.5 at % or more fluorine.

Other features and aspects will be apparent from the following detailed description, the drawings, and the claims.

### BRIEF DESCRIPTION OF THE DRAWINGS

FIG. 1 shows TGA analysis results of silicon compounds produced in Examples 1 to 4.

FIG. 2 shows DSC analysis results of silicon compounds produced in Examples 1 to 4.

### DETAILED DESCRIPTION OF EMBODIMENTS

In the present specification, unless otherwise defined, all technical terms and scientific terms have the same meanings as those commonly understood by a person skilled in the art to which the present invention pertains. The terms used herein are only for effectively describing a certain specific example and are not intended to limit the present invention.

The singular form used in the present specification may be intended to also include a plural form, unless otherwise indicated in the context.

Throughout the present specification, unless otherwise particularly stated, the word “comprising”, “being equipped with”, “containing”, or “having” a constituent element does not mean the exclusion of any other constituent element, but mean the further inclusion of other constituent elements, and elements, materials, or processes which are not further listed are not excluded.

The numerical range used in the present specification includes all values within the range including the lower limit and the upper limit, increments logically derived from the form and spanning of a defined range, all double limited values, and all possible combinations of the upper limit and the lower limit in the numerical range defined in different forms. Unless otherwise defined in the present specification, values which may be outside a numerical range due to experimental error or rounding off of a value are also included in the defined numerical range.

Unless otherwise particularly defined in the present specification, “about” may be considered as a value within 30%, 25%, 20%, 15%, 10%, or 5% of a stated value.

The term “alkyl” in the present specification is an organic radical derived from an aliphatic hydrocarbon by removal of one hydrogen, and may include both linear and branched alkyls. The alkyl may have 1 to 7, specifically 1 to 5, and more specifically 1 to 4 carbon atoms. The linear alkyl may include, as an example, methyl, ethyl, n-propyl, n-butyl, n-pentyl, n-hexyl, and n-heptyl, and the branched alkyl may include isopropyl, sec-butyl, isobutyl, tert-butyl, isopentyl, 2-methylhexyl, 3-methylbutyl, 2-methylpentyl, 3-methylpentyl, 4-methylpentyl, 2-methylhexyl, 3-methylhexyl, 4-methylhexyl, 5-methylhexyl, 2, 3-dimethylbutyl, 2, 3-dimethylpentyl, 2, 4-dimethylpentyl, and the like, but is not limited thereto.

Hereinafter, the present disclosure will be described in detail. However, it is only illustrative, and the present disclosure is not limited to the specific exemplary embodiment which is illustratively described.

An exemplary embodiment of the present invention provides a silicon compound used as a precursor of a high-quality low-dielectric silicon-containing thin film.

Specifically, the silicon compound according to an exemplary embodiment may be represented by the following Chemical Formula 1:

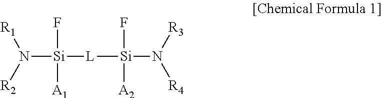

wherein

A₁ and A₂ are independently of each other hydrogen, fluoro, C1-C7 alkyl, or —N (R₁₁) (R₁₂);

L is C1-C7 alkylene; and

R₁ to R₄, R₁₁, and R₁₂ are independently of one another C1-C7 alkyl.

Since the silicon compound according to an exemplary embodiment has the structural characteristics of Chemical Formula 1, for example, a structure in which a silicon atom having at least one fluoro group and dialkylamino group is connected with an alkylene group, the silicon compound is present in a liquid state at room temperature, may have excellent volatility properties and thermal stability, allows deposition of a thin film with a high thin film deposition rate even under low temperature conditions, and may provide a low-dielectric silicon-containing thin film having high purity and excellent durability.

As an example, A₁ and A₂ may be independently of each other hydrogen, fluoro, C1-C4 alkyl, or N (R₁₁) (R₁₂); L may be C1-C4 alkylene; and R₁ to R₄, R₁₁, and R₁₂ may be independently of one another C1-C4 alkyl.

Specifically, the silicon compound according to an exemplary embodiment may be represented by the following Chemical Formula 1-1 or Chemical Formula 1-2:

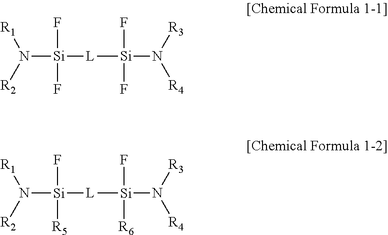

wherein

L is C1-C7 alkylene;

R₁ to R₄ are independently of one another C1-C7 alkyl;

R₅ and R₆ are independently of each other hydrogen, C1-C7 alkyl, or —N (R₁₁) (R₁₂); and

R₁₁ and R₁₂ are independently of each other C1-C7 alkyl.

As an example, L may be C1-C4 alkylene; R₁ to R₄ may be independently of one another C1-C4 alkyl; R₅ and R₆ may be independently of each other C1-C4 alkyl or —N (R₁₁) (R₁₂); and R₁₁ and R₁₂ may be independently of each other C1-C4 alkyl.

As an example, L may be methylene or ethylene.

As an example, R₁ to R₄ may be identical to each other and be C1-C4 alkyl.

As an example, R₁₁ and R₁₂ may be identical to each other and be C1-C4 alkyl.

As an example, R₁ to R₁₄, R₁₁, and R₁₂ may be identical to one another and be C1-C4 alkyl.

Specifically, the silicon compound represented by Chemical Formula 1-2 may be represented by the following Chemical Formulae 1-3 to 1-5:

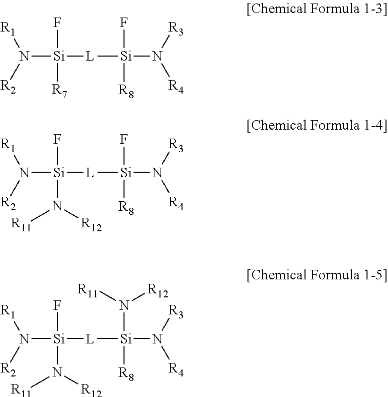

wherein

L is C1-C7 alkylene;

R₁ to R₄, R₁₁, and R₁₂ are independently of one another C1-C7 alkyl; and

R₇ and R₈ may be independently of each other hydrogen or C1-C7 alkyl.

As an example, R₇ and R₈ are independently of each other C1-C4 alkyl.

As an example, R₇ and R₈ are identical to each other and are C1-C4 alkyl.

The silicon compound according to an exemplary embodiment may be selected from the following structures, but is not limited thereto:

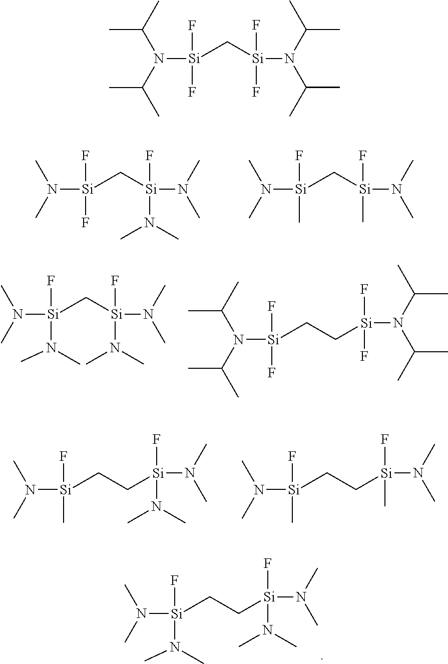

Another exemplary embodiment provides a method of producing the silicon compound.

Hereinafter, the method of producing a silicon compound according to an exemplary embodiment will be described in detail, but it may be synthesized also by a method which may be recognized by a person skilled in the art, of course, an organic solvent used herein is not limited, and a reaction time and temperature may be also changed within a range which does not depart from the gist of the invention, of course.

The silicon compound represented by the following Chemical Formula 1-1 according to an exemplary embodiment may include: reacting a compound of the following Chemical Formula 2 with compounds of Chemical Formula 11 and 12 to produce a compound of Chemical Formula 3; and reacting the compound of Chemical Formula 3 with a fluorine source to produce the silicon compound of Chemical Formula 1-1:

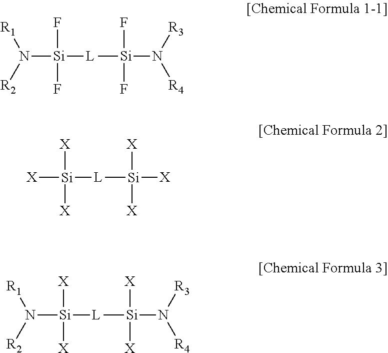

[Chemical Formula 11]

(R₁) (R₂) NH

[Chemical Formula 12]

(R₃) (R₄) NH

wherein

X is Cl or Br; and

R₁ to R₄ are independently of one another C1-C7 alkyl.

In addition, the silicon compound represented by the following Chemical Formula 1-1 according to an exemplary embodiment may include: reacting a compound of the following Chemical Formula 2 with a fluorine source to produce a compound of the following Chemical Formula 4; and reacting the compound of Chemical Formula 4 with compounds of the following Chemical Formulae 11 and 12 to produce the silicon compound of Chemical Formula 1-1:

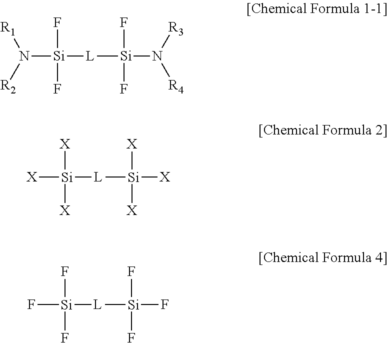

[Chemical Formula 11]

(R₁) (R₂) NH

[Chemical Formula 12]

(R₃) (R₄) NH

wherein

X is Cl or Br; and

R₁ to R₄ are independently of one another C1-C7 alkyl.

In addition, the silicon compound of the following Chemical Formula 1-3 according to an exemplary embodiment may include: reacting a compound of the following Chemical Formula 5 with a fluorine source to produce a compound of the following Chemical Formula 6; and reacting the compound of Chemical Formula 6 with compounds of the following Chemical Formulae 11 and 12 to produce the silicon compound of Chemical Formula 1-1:

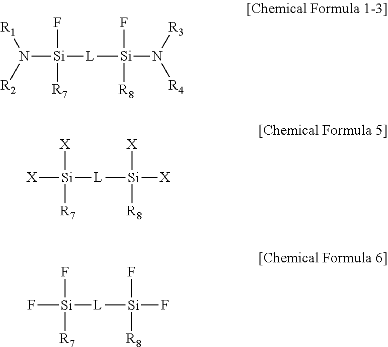

[Chemical Formula 11]

(R₁) (R₂) NH

[Chemical Formula 12]

(R₃) (R₄) NH

wherein

X is Cl or Br;

R₁ to R₄ are independently of one another C1-C7 alkyl; and

R₇ and R₈ may be independently of each other hydrogen or C1-C7 alkyl.

In addition, the silicon compound of the following Chemical Formula 1-4 according to an exemplary embodiment may include: reacting a compound of the following Chemical Formula 7 with a fluorine source to produce a compound of the following Chemical Formula 8; and reacting the compound of Chemical Formula 8 with compounds of the following Chemical Formulae 11 to 13 to produce the silicon compound of Chemical Formula 1-4:

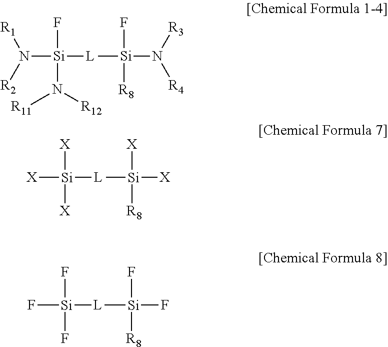

[Chemical Formula 11]

(R₁) (R₂) NH

[Chemical Formula 12]

(R₃) (R₄) NH

[Chemical Formula 13]

(R₁₁) (R₁₂) NH

wherein

X is Cl or Br;

R₁ to R₄, R₁₁, and R₁₂ are independently of one another C1-C7 alkyl; and

R₈ is hydrogen or C1-C7 alkyl.

In addition, the silicon compound of the following Chemical Formula 1-5 according to an exemplary embodiment may include: reacting a compound of the following Chemical Formula 2 with a fluorine source to produce a compound of the following Chemical Formula 4; and reacting the compound of Chemical Formula 4 with compounds of the following Chemical Formulae 11 to 13 to produce the silicon compound of Chemical Formula 1-5:

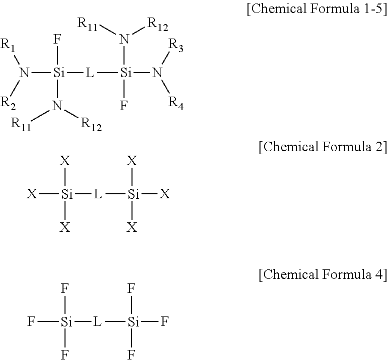

[Chemical Formula 11]

(R₁) (R₂) NH

[Chemical Formula 12]

(R₃) (R₄) NH

[Chemical Formula 13]

(R₁₁) (R₁₂) NH

wherein

x is Cl or Br; and

R₁ to R₄, R₁₁, and R₁₂ are independently of one another C1-C7 alkyl.

As an example, Chemical Formulae 11 and 12 may be the same compounds as each other.

As an example, Chemical Formulae 11 to 13 may be the same compounds as one another.

As an example, the fluorine source may be selected from alkali metal fluorides such as LiF, KF, NaF, RbF, and CsF or transition metal fluorides such as AgF, AgF₂, ZnF₂, CuF₂, CuF₂·H₂O, NiF₂, SnF₂, InF₃, ScF₃, TiF₃, MnF₃, CoF₃, CrF₃, AuF₃, FeF₃, MnF₃, BiF₃, and SbF₃, but is not limited thereto.

Another exemplary embodiment of the present invention provides a composition for depositing a silicon-containing thin film including the silicon compound.

The composition for depositing a silicon-containing thin film according to an exemplary embodiment includes the silicon compound represented by Chemical Formula 1 as a precursor for depositing a thin film, and the content of the compound represented by Chemical Formula 1 in the composition may be included within a range which may be recognized by a person skilled in the art considering the film formation conditions of a thin film, the thickness of a thin film, the characteristics of a thin film, the use of a thin film, and the like.

Another exemplary embodiment of the present invention provides a method of producing a silicon-containing thin film, which uses a silicon compound represented by the following Chemical Formula 1 or a composition for depositing a silicon-containing thin film including the compound:

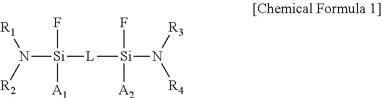

wherein

L, R₁ to R₄, A₁, and A₂ are as defined above in Chemical Formula 1.

Since the method of producing a silicon-containing thin film according to an exemplary embodiment uses the silicon compound represented by Chemical Formula 1 as a precursor, a high-quality silicon-containing thin film may be produced with a high deposition rate even at a low temperature and low power.

Specifically, the silicon-containing thin film according to an exemplary embodiment may be a fluorine and silicon-containing thin film, and the method of producing a silicon-containing thin film according to an exemplary embodiment may provide a low-dielectric constant high-quality fluorine and silicon-containing thin film, since the fluorine (F) of the silicon compound represented by Chemical Formula 1 remains the thin film.

Specifically, the silicon-containing thin film according to an exemplary embodiment may contain 0.5 at % or more, 1.0 at % or more, 1.5 at % or more, 2.0 at % or more, 2.5 at % or more and 10 at % or less, 9 at % or less, 8 at % or less, or 7 at % or less of fluorine.

The silicon-containing thin film according to an exemplary embodiment may be any thin film which is produced within a range which may be recognized by a person skilled in the art, and specifically, may be a silicon oxide film (SiO₂), a silicon nitride film (SiN), a silicon carbonitride film (SiCN), a silicon carbide film (Sic), a fluorinated silicon oxide film (SiOF), a fluorinated silicon carbide film (SiCF), a fluorinated silicon carbonitride film (SiCNF), a fluorinated silicon oxynitride film (SiONF), and the like, and other than that, various high-quality thin films containing silicon or fluorine and silicon may be produced within a range which may be recognized by a person skilled in the art.

The silicon-containing thin film according to an exemplary embodiment has both excellent chemical and thermal stability and may be used for various uses, for example, as an insulating film, a diffusion barrier, a spacer, an intermetallic dielectric material, a protective film layer, and the like in the production of electronic devices.

In the method of producing a silicon-containing thin film according to an exemplary embodiment, the silicon precursor and the reaction gas may be supplied organically or independently of each other. In addition, the silicon precursor and the reaction gas may be continuously or discontinuously supplied, and discontinuous supply may include a pulse form.

As an example, the method of producing a silicon-containing thin film according to an exemplary embodiment may include:

a) maintaining a temperature of a substrate mounted in a chamber at 100°° C. or higher;

b) bringing the silicon compound according to an exemplary embodiment of the present invention or a composition for depositing a silicon-containing thin film into contact with the substrate to adsorb the compound or the composition onto the substrate; and

c) injecting a reaction gas into the substrate on which the silicon compound or the composition for depositing a silicon-containing thin film is adsorbed to form a silicon-containing thin film.

Specifically, the method of producing a silicon-containing thin film may include:

a) maintaining a temperature of a substrate mounted in a chamber at 100°° C. or higher;

b) bringing the silicon compound according to an exemplary embodiment of the present invention or a composition for depositing a silicon-containing thin film into contact with the substrate to adsorb the compound or the composition onto the substrate;

c) purging a residual silicon compound or a residual composition for deposition a thin film and a by-product;

d) injecting a reaction gas into the substrate on which the silicon compound or the composition for depositing a thin film is adsorbed to form a silicon-containing thin film; and

e) purging a residual reaction gas and by-products.

In addition, as an example, the method of producing a silicon-containing thin film may include:

maintaining a temperature of a substrate mounted in a chamber at 100°° C. or higher; and

injecting the silicon compound of Chemical Formula 1 or a composition for depositing a silicon-containing thin film including the compound and a reaction gas simultaneously to deposit a silicon-containing thin film.

A method of depositing a thin film in the method of producing a silicon-containing thin film according to an exemplary embodiment is not particularly limited as long as it is commonly used in the art, but, for example, thermal chemical vapor deposition (TCVD), atomic layer deposition (ALD), chemical vapor deposition (CVD), metal organic chemical vapor deposition (MOCVD), low pressure chemical vapor deposition (LPCVD), plasma enhanced chemical vapor deposition (PECVD), or plasma enhanced atomic layer deposition (PEALD) may be used, and specifically, atomic layer deposition (ALD) or thermal chemical vapor deposition (TCVD) may be used, but is not limited thereto.

Though the substrate is not particularly limited as long as it is commonly used in the art, it may be, for example, a substrate including one or more semiconductor materials among Si, Ge, SiGe, GaP, GaAs, SiC, SiGeC, InAs, and InP; a silicon on insulator (SOI) substrate; a quartz substrate; a glass substrate for display; or a flexible plastic substrate such as polyimide (PI), polyethylene terephthalate (PET), polyethylene naphthalate (PEN), polymethyl methacrylate (PMMA), polycarbonate (PC), polyethersulfone (PES), and polyester.

In addition, the silicon-containing thin film may be formed directly on the substrate, but also, a plurality of conductive layers, dielectric layers, insulating layers, or the like may be further formed between the substrate and the silicon-containing thin film.

As an example, a temperature of the substrate may be specifically 100 to 1,000° C., 300 to 1,000° C., or 500 to 1,000° C., and under the temperature conditions, fluorine (F) of the silicon compound represented by Chemical Formula 1 may be allowed to remain in the thin film, a high-quality fluorine and silicon-containing thin film may be provided, and a thin film having a lower dielectric constant may be provided.

As an example, the reaction gas may be supplied after being activated by generating plasma at 50 to 1,000 W, 100 to 800 W, or 400 to 600 W.

The type of reaction gas is not particularly limited as long as it is commonly used in the art, but as an example, may be oxygen (Oz), ozone (O₃), oxygen plasma, hydrogen (H₂), hydrogen plasma, water (H₂O), hydrogen peroxide (H₂O₂), nitrogen dioxide (NO₂), nitrogen monoxide (NO), nitrous oxide (N₂O), ammonia (NH₃), carbon dioxide (CO₂), formic acid (HCOOH), acetic acid (CH₃COOH), anhydrous acetic acid ((CH₃CO)₂O), or a combination thereof. A gas for purging may be nitrogen (N₂), argon (Ar), helium (He), or a combination thereof.

In the method of producing a silicon-containing thin film according to an exemplary embodiment, deposition conditions may be adjusted depending on the structure or thermal properties of the thin film to be desired, and the deposition conditions according to an embodiment may be, for example, an input flow rate of the silicon precursor, input flow rates of the reaction gas and the carrier gas, pressure, RF power, a substrate temperature, and the like. As a non-limiting example, the input flow rate of the silicon precursor may be 10 to 1000 cc/min, the input flow rate of the carrier gas may be 10 to 1000 cc/min, the flow rate of the reaction gas may be 1 to 5000 cc/min, the pressure may be 0.5 to 10 torr, and the RF power and the substrate temperature may be as described above.

Hereinafter, the exemplary embodiments described above will be described in detail through the following examples. However, the following examples are only for description, and do not limit the right scope.

The physical properties of the examples were measured as follows:

### 1) Thermal Properties

In order to measure the thermal stability, the volatility, and the decomposition temperature of the silicon compound, thermogravimetric analysis (TGA, L81-II, LINSEIS) and differential scanning calorimeter (DSC) were used.

### 2) Thickness

An ellipsometer (OPTI-PROBE 2600, THERMA-WAVE) was used to measure the thickness of a silicon-containing thin film.

### 3) Refractive Index

The refractive index of the deposited thin film was measured using an ellipsometer (Spectroscopic Ellipsometer, Elli-SE-Uam12, Ellipso technology).

### <Production of Silicon Compound>

### EXAMPLE 1

### Bis (difluoro-di-iso-propylaminosilyl) methane

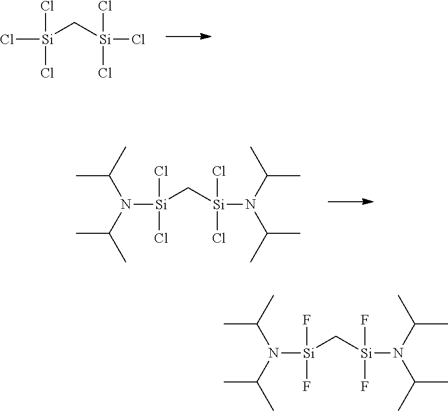

A reflux device was installed in a flame-dried 1 L flask under an anhydrous and inert atmosphere, 375 g (1.33 mol) of bis (trichlorosilyl) methane and 1713 g (19.88 mol) of n-hexane were added thereto, the temperature was cooled to −20° C. or lower while stirring, and diisopropylamine was slowly added while the internal temperature was maintained at 0°° C. After completing the addition of diisopropylamine, the temperature was slowly raised to room temperature, stirring was performed at 80°° C. for 6 hours, the reaction mixture after the reaction was filtered, and the solvent was removed under reduced pressure to obtain 513 g of bis (dichloro-di-iso-propylaminosilyl) methane (yield: 93.78%, 1.25 mol).

712 g (3.98 mol) of SbF3 and 718 g (9.95 mol) of n-pentane were added to a flame-dried 2 L flask under an anhydrous and inert atmosphere, 513 g of bis (dichloro-di-iso-propylaminosilyl) methane was slowly added thereto at room temperature. After completing the addition, stirring was performed at room temperature for 3 hours, the reaction mixture after the reaction was filtered, the solvent was removed under reduced pressure from the filtrate, and purification under reduced pressure was performed under the conditions of 67 to 68° C. and 0.34 torr to obtain 321 g (0.927 mol) of bis (difluoro-di-iso-propylaminosilyl) methane as a target compound (yield: 70%, GC purity: 98.5%).

¹H NMR (CDCl₃): 0.22 ppm (m, 2H, Si—CH₂—Si), 1.09 ppm (d, 24H, Si—N [(CH) (CH₃)₂)]₂), 3.05 (m, 4H, Si-ppm N [(CH) (CH₃)₂)]₂)

²⁹Si NMR (CDCl₃): −37.66 ppm (t, 2Si, Si—CH₂—Si)

### EXAMPLE 2

### 1, 4-difluoro-1, 1, 4-tris (dimethylamino)-1, 4-disilapentane

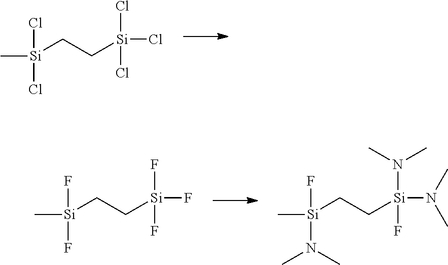

2211 g (12.37 mol) of SbF₃ and 2371 g (17.67 mol) of diethylene glycol dimethyl ether were added to a flame-dried 5 L flask under an anhydrous and inert atmosphere, 1000 g (3.62 mol) of 1,1, 1-4, 4-penta-chloro-1, 4-disilapentane was slowly added dropwise at room temperature, stirring was performed for 3 hours, the reaction mixture after reaction was filtered, and the filtrate was fractionally distilled at 120 to 140° C. and 760 torr to obtain 462 g (2.38 mol) of 1,1,1,4, 4-penta-fluoro-1,4-disilapentane (yield: 65%).

1987 g (5.02 mol) of 2.53 M n-BuLi and 2600 g (30.10 mol) of n-hexane were added to a flame-dried 10 L flask under an anhydrous and inert atmosphere, the temperature was lowered to −20°° C., and 508 g (5.02 mol) of dimethylamine was slowly added while the temperature was maintained at 0° C. or lower to produce a lithium dimethylamine salt.

462 g (2.38mol) of 1, 1, 1-4, 4-penta-fluoro-1, 4-disilapentane and 2160 g (25.08 mol) of n-hexane were added to a flame-dried 10 L flask under an anhydrous and inert atmosphere, the temperature was lowered to −20° C., and the lithiumdimethyl amine salt was slowly added while the temperature was maintained at −10° C. or lower. After completing the addition, the temperature of the reaction mixture was raised to room temperature, stirring was performed for 6 hours, and the reaction mixture after the reaction was filtered to obtain a filtrate, the solvent was removed from the filtrate under reduced pressure, and purification under reduced pressure under 42° C. and 0.40 torr conditions to obtain 522 g of 1, 4-difluoro-1, 1, 4-tris (dimethylamino)-1, 4-disilapentane (1.51 mol, yield: 60%).

¹H NMR (C₆D₆): 0.22 ppm (d, 3H, Si—CH₃), 0.75 ppm (m, 4H, Si—CH₂—CH₂—Si), 2.37 ppm (d, 6H, CH₃—Si—N [CH₃]₂), 2.31 ppm (s, 6H, F—CH₃—Si—{N [CH₃]₂}), 2.37 ppm (s, 12H, F—Si—{N [CH₃]₂}₂).

### EXAMPLE 3

### Bis ((fluoro-methyl-di-methylamino) silyl) ethane

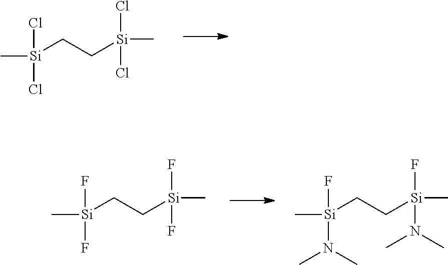

405 g (15.62 mol) of LiF and 1351 g (18.74 mol) of

THF were added to a flame-dried 5 L flask under an anhydrous and inert atmosphere, 800 g (3.21 mol) of bis (dichloromethylsilyl) methane was slowly added dropwise, stirring was performed for 3 hours, the reaction mixture after the reaction was filtered, the filtrate was separated and purified through fractional distillation at 68° C. and 760 torr to obtain 416 g (2.19 mol) of bis (difluoromethylsilyl) methane (yield: 70%).

1840 g (4.60 mol) of 2.5 M n-BuLi and 2300 g (18.40 mol) of n-hexane were added to a flame-dried 10 L flask under an anhydrous and inert atmosphere, the temperature was lowered to −20° C., and 207 g (4.60 mol) of dimethylamine was slowly added while the temperature was maintained at 0° C. or lower to produce a lithium dimethylamine salt.

416 g (2.19 mol) of bis (difluoromethylsilyl) methane and 1700 g (21.89 mol) of n-hexane were added to a flame-dried 10 L flask under an anhydrous and inert atmosphere, the temperature was lowered to −20° C., and 235 g (4.60 mol) of the produced lithium dimethylamine salt was slowly added while the temperature was maintained at −10° C. or lower. After completing the addition, the reaction mixture was slowly heated to room temperature, stirring was performed for 6 hours, the reaction mixture was filtered, the solvent was removed under reduced pressure from the filtrate, and purification under reduced pressure was performed under 72° C. and 6.0 torr conditions to obtain 300 g (1.25 mol) of bis (fluoro-di-methylaminomethylsilyl) ethane (yield: 53%).

¹H NMR (C₆D₆): 0.08 ppm (d, 6H, Si—CH₃), 0.64 ppm (S, 4H, Si—CH₂—CH₂—Si), 2.36 ppm (d, 12H, Si—{N [CH₃]₂}₂)

### EXAMPLE 4

### 1, 4-difluoro-1, 1, 4, 4-tetra (dimethlylamino)-1, 4-disilabutane

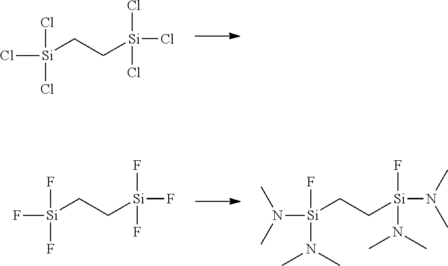

1200 g (26.62 mol) of LiF and 1874 g (13.97 mol) of diethylene glycol dimethyl ether were added to a flame-dried 5 L flask under an anhydrous and inert atmosphere, 790 g (2.66 mol) of bis (trichloromsilyl) ethane was slowly added at room temperature, stirring was performed for 3 hours, the reaction mixture was filtered, and then fractional distillation was performed at 60°° C. and 760 torr to obtain 370 g (1.86 mol) of bis (trifluorosilyl) ethane (yield: 70%).

2982 g (7.45 mol) of 2.5 M n-BuLi and 2570 g (29.82 mol) of n-hexane were added to a flame-dried 10 L flask under an anhydrous and inert atmosphere, the temperature was lowered to −20°° C., and 336 g (7.45 mol) of dimethylamine was slowly added while the temperature was maintained at 0° C. or lower to produce a lithium dimethylamine salt.

370 g (1.86 mol) of bis (trifluorosilyl) ethane and 1300 g (15 mol) of n-hexane were added to a flame-dried 10 L flask under an anhydrous and inert atmosphere, the temperature was lowered to −20° C., and 336 g (7.45 mol) of the produced lithium dimethylamine salt was slowly added while the temperature was maintained at −10° C. or lower. After completing the addition, the reaction mixture was slowly heated to room temperature, stirring was performed for 6 hours, the reaction mixture was filtered, the solvent was removed under reduced pressure from the filtrate, and purification under reduced pressure was performed under 58° C. and 0.3 torr conditions to obtain 417 g (1.39 mol) of 1,4-difluoro-1, 1, 4, 4-tetra (dimethlylamino)-1, 4-disilabutane (yield: 75%).

¹H NMR (C₆D₆): 0.65 ppm (S, 4H, Si—CH₂—CH₂—Si), 2.38ppm (d, 24H, (Si-{N [CH₃]₂}₂) ₂)

### EXAMPLE 5

### Bis (difluoro-di-iso-propylaminosilyl) methane

A reflux device was installed in a flame-dried 1 L flask under an anhydrous and inert atmosphere, 375 g (1.33 mol) of bis (trichlorosilyl) methane and 1713 g (19.88 mol) of n-hexane were added, the temperature was lowered to −20° C. or lower while stirring, and then diisopropylamine was slowly added while the internal temperature was maintained at 0° C. or lower. After completing the addition of diisopropylamine, the temperature was slowly raised to room temperature, stirring was performed at 80° C. for 6 hours, the reaction mixture after the reaction was filtered, and the solvent was removed under reduced pressure to obtain 513 g of bis (dichloro-di-iso-propylaminosilyl) methane (yield: 93.78%, 1.25 mol).

290 g (7.96 mol) of LiF and 556 g (10.64 mol) of an acetonitrile (CH₃CN, acetonitrile) solvent or 510 g (7.03 mol) of a THF solvent were added to a flame-dried 2 L flask under an anhydrous and inert atmosphere, and 513 g (1.24 mol) of bis (dichloro-di-iso-propylaminosilyl) methane was slowly added at room temperature. After completing the addition, stirring was performed at 80° C. for 6 hours, the reaction mixture after the reaction was filtered, the solvent was removed under reduced pressure from the filtrate, and drying under reduced pressure was performed under 67 to 68° C. and 0.34 torr conditions to obtain 229 g of bis (difluoro-di-iso-propylaminosilyl) methane as a target compound (yield: 50%).

¹H NMR (CDCl₃): 0.22 ppm (m, 2H, Si—CH₂—Si), 1.09 ppm (d, 24H, Si—[(CH) (CH₃)₂)]₂), 3.05 ppm (m, 4H, Si—N [(CH) (CH₃)₂)]₂)

²⁹Si NMR (CDCl₃): −37.66 ppm (t, 2Si, Si—CH₂—Si)

### EXAMPLE 6

### Bis (difluoro-di-iso-propylaminosilyl) methane

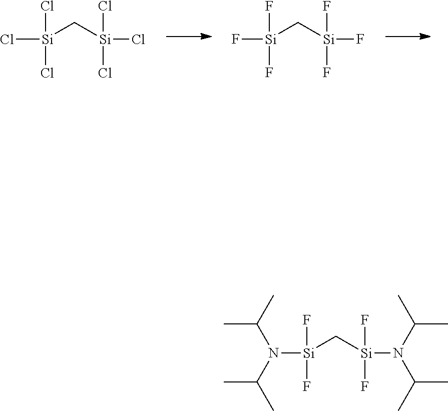 [SMILES: Cl[Si](Cl)(Cl)C[Si](Cl)(Cl)Cl ; F[Si](F)(F)C[Si](F)(F)F ; CC(C)N(C(C)C)[Si](F)(F)C[Si](F)(F)N(C(C)C)C(C)C]

973 g (5.44 mol) of SbF3 and 1043 g (7.78 mol) of diethylene glycol dimethyl ether were added to a flame-dried 1 L flask under an anhydrous and inert atmosphere, and 440 g (1.56 mol) of bis (trichlorosilyl) methane was slowly added dropwise at room temperature. Stirring was performed at room temperature for 6 hours, and simple distillation was performed under 145° C. and 760 torr conditions to obtain 160 g of bistrifluorosilylmethane (yield: 56%).

103 g (1.02 mol) of diisopropylamine and 440 g (6.10 mol) of n-pentane were added to a flame-dried 1 L flask under an anhydrous and inert atmosphere, the temperature was lowered to −20° C. or lower, and 403 g (1.02 mol) of 2.53 M n-BuLi was slowly added to produce a lithium diisopropylamine salt.

160 g (0.87 mol) of bis (trifluorosilyl) methane and 400 g (5.22 mol) of dimethoxymethane were added to a flame-dried 1 L flask under an anhydrous and inert atmosphere, the temperature was lowered to −20° C., and the lithium diisopropylamine salt produced above was slowly added while the temperature was maintained at 0° C. or lower. After completing the addition, the temperature was raised to room temperature, stirring was performed at room temperature for 6 hours, the reaction mixture after the reaction was filtered to obtain a filtrate, the solvent was removed under reduced pressure from the obtained filtrate, and purification under reduced pressure was performed under 67 to 68° C. and 0.34 torr to obtain 375 g of bis (difluoro-di-iso-propylaminosilyl) methane (yield: 50%, 1.08 mol).

¹H NMR (CDCl₃): 0.22 ppm (m, 2H, Si—CH₂—Si), 1.09 ppm (d, 24H, Si—N [(CH) (CH₃)₂)]₂), 3.05 ppm (m, 4H, Si—N [(CH) (CH₃)₂)]₂)

²⁹Si NMR (CDCl₃): −37.66 ppm (t, 2Si, Si—CH₂—Si)

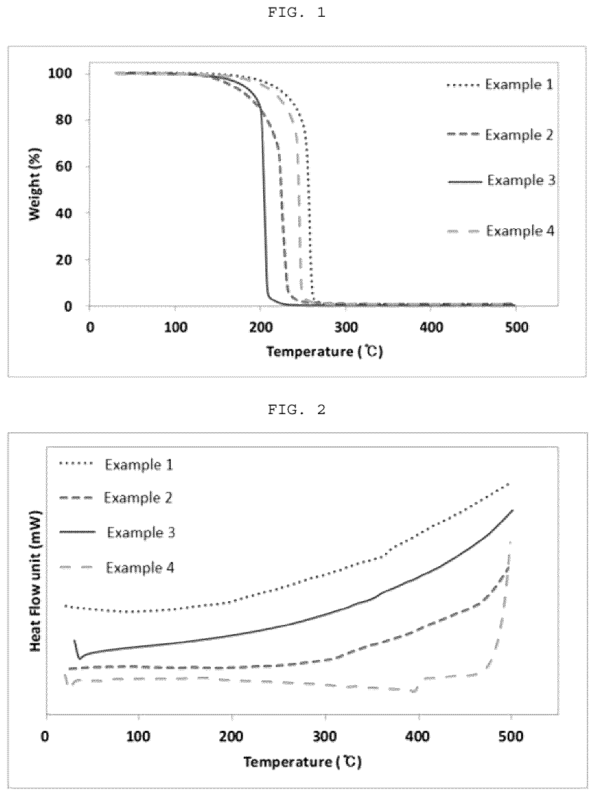

FIGS. 1 and 2 show thermogravimetric analysis (TGA) and differential scanning calorimetry (DSC) analysis results of the silicon compounds obtained in Examples 1 to 4. Referring to FIG. 1, it was found that the compounds of the examples all had a single evaporation step at about 200 to 300° C., there was almost no residue mass and rapid vaporization characteristics were shown, and it was found that the silicon compounds of the examples of the present invention all had excellent thermal stability.

### <Deposition of Silicon-Containing Thin Film>

### EXAMPLE 7

### Thermal Chemical Vapor Deposition (TCVD) Using Silicon Compound of Example 1

In a common thermal chemical vapor deposition (TCVD) device, bis (difluoro-di-iso-propylaminosilyl) methane which is the silicon compound obtained in Example 1 was used as the silicon precursor for forming the silicon oxide film to perform thin film evaluation under 900°° C. conditions. Oxygen was used as a reaction gas, and argon was used as a base gas.

The temperature of the silicon substrate was set to 900° C. conditions, a stainless steel bubbler container was filled with the silicon precursor, and the temperature was maintained at 120° C. First, the silicon precursor vaporized in the stainless steel bubbler container was transferred to a silicon substrate for 5 minutes using 100 sccm of argon gas as a transfer gas and adsorbed onto the silicon substrate, and simultaneously, 2000 sccm of oxygen as the reaction gas was flowed to form a silicon oxide film.

Hereinafter, the detailed deposition conditions of the silicon oxide film are shown in Table 1, and the thickness, the growth rate, and the refractive index of the deposited silicon oxide film were measured and are shown in the following Table 2.

TABLE 1

| | | | Bis((difluoro-di-iso- |
|---|---|---|---|
| | Silicon precursor | | propylamino)silyl)methane |
| Method of depositing silicon | | | Thermal chemical vapor |
| oxide film | | | deposition (TCVD) |
| Substrate temperature (° C.) | | | 900° C. |
| | Silicon | Heating | 120 |
| | precursor | temperature (° C.) | |
| | | Transfer gas | Ar (100 sccm) |
| | Reaction gas | Oxygen flow rate | 2000 |
| | | (sccm) | |

| | |
|---|---|
| Deposition time (min) | 5 |

TABLE 2

| | | Silicon | | | | |
|---|---|---|---|---|---|---|
| | | precursor | Oxygen | | | |
| | Substrate | heating | flow | Film | Growth | |
| Deposition | temperature | temperature | rate | thickness | rate | Refractive |
| method | (° C.) | (° C.) | (sccm) | [Å] | [Å/min] | index |
| TCVD | 900 | 120 | 2000 | 290 | 58 | 1.45 |

### EXAMPLE 8

### Thermal Chemical Vapor Deposition (TCVD) Using Silicon Compound of Example 2

In a common thermal chemical vapor deposition (TCVD) device, 1,4-difluoro-1,1,4-tris (dimethylamino)-1,4-disilapentane which is the silicon compound obtained in Example 2 was used as the silicon precursor for forming the silicon oxide film to perform thin film evaluation under 900° C. conditions. Oxygen was used as a reaction gas, and argon was used as a base gas.

The temperature of the silicon substrate was set to 630 to 900°° C. conditions, a stainless steel bubbler container was filled with the silicon precursor, and the temperature was maintained at 70 to 100° C. First, the silicon precursor vaporized in the stainless steel bubbler container was transferred to a silicon substrate for 5 to 10 minutes using 100 sccm of argon gas as a transfer gas and adsorbed onto the silicon substrate, and simultaneously, 2000 sccm of oxygen as the reaction gas was flowed to form a silicon oxide film.

Hereinafter, the detailed deposition conditions of the silicon oxide film are shown in Table 3, and the thickness, the growth rate, and the refractive index of the deposited silicon oxide film were measured and are shown in the following Table 4.

TABLE 3

| | | 1,4-difluoro-1,1,4-tris(dimethylamino)- |
|---|---|---|
| Silicon precursor | | 1,4-disilapentane |
| Method of depositing | | Thermal chemical vapor deposition |
| silicon oxide film | | (TCVD) |
| Substrate temperature (° C.) | | 630, 900° C. |
| Silicon | Heating | 70-100 |
| precursor | temperature | |
| | (° C.) | |
| | Transfer gas | Ar (100 sccm) |
| Reaction gas | Oxygen flow | 2000 |
| | rate (sccm) | |

| | |
|---|---|
| Deposition time (min) | 5, 10 |

TABLE 4

| | | Silicon | | | |
|---|---|---|---|---|---|
| | | precursor | Oxygen | | |
| | Substrate | heating | flow | Growth | |
| Deposition | temperature | temperature | rate | rate | Refractive |
| method | (° C.) | (° C.) | (sccm) | [Å/min] | index |
| TCVD | 630 | 100 | 2000 | 6.6 | 1.69 |
| | 900 | 70 | 2000 | 14.4 | 1.53 |

### EXAMPLE 9

### Atomic Layer Deposition (ALD) Using Silicon Compound of Example 2

In a common atomic layer deposition (ALD) device, 1,4-difluoro-1,1,4-tris (dimethylamino)-1,4-disilapentane which is the silicon compound obtained in Example 2 was used as the silicon precursor for forming the silicon oxide film to perform thin film evaluation under 630° C. conditions, and oxygen was used as a reaction gas and argon was used as a purge gas.

A silicon substrate was set under 630° C. conditions, a stainless steel bubbler container was filled with the silicon precursor, and the temperature was maintained at 100° C. First, the silicon precursor vaporized in the stainless steel bubbler container was transferred to a silicon substrate for 5 seconds using 100 sccm of an argon gas as a transfer gas and adsorbed onto the silicon substrate. Second, the unadsorbed silicon precursor was removed for about 10 seconds using 1,000 sccm of the argon gas; third, as the reaction gas, 2,000 to 4,000 sccm of oxygen was flowed for 5 to 20 seconds or 2000 sccm of oxygen was flowed for 5 seconds to form a silicon oxide film; and finally, the reaction by-product and residual reaction gas were removed for about 10 seconds using 1,000 sccm of the argon gas. The above-described process was set as 1 cycle, and a certain cycle was repeated to form a silicon oxide film.

Hereinafter, the detailed deposition method of a silicon oxide film is shown in Table 5, and the thickness, the growth rate, and the refractive index of the deposited silicon oxide film were measured and are shown in the following Table 6.

TABLE 5

| | | 1,4-difluoro-1,1,4-tris(dimethylamino)- |
|---|---|---|
| Silicon precursor | | 1,4-disilapentane |
| Method of depositing silicon | | Atomic layer deposition (ALD) |
| oxide film | | |
| Substrate temperature (° C.) | | 630 |
| Silicon | Heating | 100 |
| precursor | temperature | |
| | (° C.) | |
| | Injection time | 5 |
| | (sec) | |
| Purge gas | Flow rate | 1000 |
| | (sccm) | |
| | Time (sec) | 10 |
| Reaction gas | Oxygen flow | 2000-4000 |
| | rate (sccm) | |
| | Time (sec) | 5, 5, 10, 20 |
| | Flow rate | 1000 |
| | (sccm) | |
| Purge gas | Time (sec) | 10 |
| | Cycle | 400 |

TABLE 6

| | Substrate | Oxygen flow | Reaction gas | | |
|---|---|---|---|---|---|
| Deposition | temperature | rate | injection | Growth rate | Refractive |
| method | (° C.) | (sccm) | time (sec) | [Å/min] | index |
| ALD | 630 | 2000 | 5 | 0.26 | 1.78 |
| | | 4000 | 5 | 0.31 | 1.93 |
| | | 4000 | 10 | 0.34 | 1.89 |
| | | 4000 | 20 | 0.30 | 1.70 |

The atom-specific content values of the silicon oxide film deposited under 630°° C. conditions were analyzed using X-ray photoelectron spectrometer and are summarized in the following Table 7. As a result, C, N, and F compositions other than the SiOₓ thin film were confirmed.

TABLE 7

| Substrate | Oxygen | Reaction gas | | | | | |
|---|---|---|---|---|---|---|---|
| temperature | flow rate | injection | Composition of film (at %) | | | | |
| (° C.) | (sccm) | time (sec) | C | N | O | Si | F |
| 630 | 2000 | 5 | 13.0 | 12.0 | 32.9 | 37.7 | 4.5 |
| | 4000 | 5 | 11.0 | 11.5 | 37.0 | 36.6 | 3.9 |
| | 4000 | 10 | 7.7 | 10.9 | 41.6 | 36.4 | 3.4 |
| | 4000 | 20 | 4.1 | 9.6 | 45.7 | 38.0 | 2.7 |

### EXAMPLE 10

### Thermal Chemical Vapor Deposition (TCVD) Using Silicon Compound of Example 3

In a common thermal chemical vapor deposition (TCVD) device, bis (difluoro-di-methylaminosilyl) ethane which is the silicon compound obtained in Example 3 was used as the silicon precursor for forming the silicon oxide film to perform thin film evaluation under 630 to 900° C. conditions. Oxygen was used as a reaction gas, and argon was used as a base gas.

A silicon substrate was set under 630°° C. conditions, a stainless steel bubbler container was filled with the silicon precursor, and the temperature was maintained at 84° C. First, the silicon precursor vaporized in the stainless steel bubbler container was transferred to a silicon substrate for 5 minutes using 100 sccm of an argon gas as a transfer gas and adsorbed onto the silicon substrate, and simultaneously, as the reaction gas, 2000 to 4000 sccm of oxygen or 4000 sccm of oxygen and 2000 sccm of hydrogen were flowed to form a silicon oxide film.

Hereinafter, the detailed deposition conditions of the silicon oxide film are shown in Table 8, and the thickness, the growth rate, and the refractive index of the deposited silicon oxide film were measured and are shown in the following Table 9.

TABLE 8

| | Silicon precursor | | Bis(difluoro-di-methylaminosilyl)ethane |
|---|---|---|---|
| Method of depositing silicon | | | Thermal chemical vapor deposition (TCVD) |
| oxide film | | | |
| Substrate temperature (° C.) | | | 630, 900 |
| | Silicon | Heating | 84 |
| | precursor | temperature | |
| | | ( ° C.) | |
| | | Transfer gas | Ar (100 sccm) |
| | Reaction gas | Oxygen flow | 2000, 4000 |
| | | rate (sccm) | |
| | | Hydrogen flow | 2000 |
| | | rate (sccm) | |

| | |
|---|---|
| Deposition time (min) | 5 |

TABLE 9

| | | Silicon | | | | |
|---|---|---|---|---|---|---|
| | | precursor | Oxygen | Hydrogen | | |
| | Substrate | heating | flow | flow | Growth | |
| Deposition | temperature | temperature | rate | rate | rate | Refractive |
| method | (° C.) | (° C.) | (sccm) | (sccm) | [Å/min] | index |
| TCVD | 630 | 84 | 2000 | — | 7.07 | 2.08 |
| | | | 4000 | — | 8.14 | 2.27 |
| | | | 4000 | 2000 | 4.66 | 2.31 |
| | 900 | | 4000 | — | 32.81 | 1.65 |

### EXAMPLE 11

### Atomic Layer Deposition (ALD) Using Silicon Compound of Example 3

In a common atomic layer deposition (ALD) device,

bis (difluoro-di-methylaminosilyl) ethane which is the silicon compound obtained in Example 3 was used as the silicon precursor for forming the silicon oxide film to perform thin film evaluation under 630°° C. conditions. Oxygen was used as a reaction gases, and argon was used as a purge gas.

A silicon substrate was set under 630° C. conditions, a stainless steel bubbler container was filled with the silicon precursor, and the temperature was maintained at 84° C. First, the e silicon precursor vaporized in the stainless steel bubbler container was transferred to a silicon substrate for 1 to 5 seconds using 100 sccm of an argon gas as a transfer gas and adsorbed onto the silicon substrate. Second, the unadsorbed silicon precursor was removed for about 10 seconds using 1,000 sccm of the argon gas; third, as the reaction gas, 2, 000 sccm of oxygen was flowed for 1 to 5 seconds to form a silicon oxide film; and finally, the reaction by-product and residual reaction gas were removed for about 10 seconds using 1,000 sccm of the argon gas. The above-described process was set as 1 cycle, and a certain cycle was repeated to form a silicon oxide film.

Hereinafter, the detailed deposition method of a silicon oxide film is shown in Table 10, and the thickness, the growth rate, and the refractive index of the deposited silicon oxide film were measured and are shown in the following Table 11.

TABLE 10

| | Bis(difluoro-di- |
|---|---|
| Silicon precursor | methylaminosilyl)ethane |

| Method of depositing silicon | | Atomic layer deposition (ALD) |
|---|---|---|
| oxide film | | |
| Substrate temperature (° C.) | | 630 |
| Silicon | Heating | 84 |
| precursor | temperature | |
| | (° C.) | |
| | Injection | |
| | time (sec) | |
| Purge gas | Flow rate | 1000 |
| | (sccm) | |
| | Time (sec) | 10 |
| Reaction gas | Oxygen flow | 2000 |
| | rate (sccm) | |
| | Time (sec) | 1, 5 |
| Purge gas | Flow rate | 1000 |
| | (sccm) | |
| | Time (sec) | 10 |
| Number of | Cycle | 400 |
| depositions | | |

TABLE 11

| | | Silicon | Reaction | | |
|---|---|---|---|---|---|
| | | precursor | gas | | |
| | Substrate | injection | injection | Growth | |
| Deposition | temperature | time | time | rate | Refractive |
| method | (° C.) | (sec) | (sec) | [Å/min] | index |
| ALD | 630 | 1 | 1 | 0.08 | 2.91 |
| | | 5 | 5 | 0.21 | 2.15 |

The atom-specific content values of the silicon oxide film deposited under 630° C. conditions were analyzed using X-ray photoelectron spectrometer and are summarized in the following Table 12. As a result, C, N, and F compositions other than the SiOₓ thin film were confirmed.

TABLE 12

| | Silicon | Reaction gas | | | | | |
|---|---|---|---|---|---|---|---|
| Substrate | precursor | injection | | | | | |
| temperature | injection | time | Composition of film (at %) | | | | |
| (° C.) | time (sec) | (sec) | C | N | O | Si | F |
| 630 | 5 | 5 | 14.0 | 8.1 | 34.3 | 39.7 | 3.8 |

### EXAMPLE b 12

### Atomic Layer Deposition (ALD) Using Silicon Compound of Example 4

In a common atomic layer deposition (ALD) device, 1,4-difluoro-1,1,4,4-tetra (dimethlylamino)-1,4-disilabutane which is the silicon compound obtained in Example 4 was used as the silicon precursor for forming the silicon oxide film to perform thin film evaluation under 630° C. conditions. Oxygen and hydrogen were used as reaction gases, and argon was used as a purge gas.

A silicon substrate was set under 630° C. conditions, and a stainless steel bubbler container was filled with the silicon precursor, and the temperature was maintained at 80 to 100° C. First, the silicon precursor vaporized in the stainless steel bubbler container was transferred to a silicon substrate for 5 to 20 seconds using 100 sccm of an argon gas as a transfer gas and adsorbed onto the silicon substrate. Second, the unadsorbed silicon precursor was removed for about 10 seconds using 1,000 sccm of the argon gas; third, as the reaction gas, 800 to 4000 sccm of oxygen was flowed for 2.5 to 10 seconds or 4000 sccm of oxygen and 5 to 20 sccm of hydrogen were flowed for 5 seconds to form a silicon oxide film; and finally, the reaction by-product and residual reaction gas were removed for about 10 seconds using 1,000 sccm of the argon gas. The above-described process was set as 1 cycle, and a certain cycle was repeated to form a silicon oxide film.

Hereinafter, the detailed deposition conditions of the silicon oxide film are shown in Table 13, and the thickness, the growth rate, and the refractive index of the deposited silicon oxide film were measured and are shown in the following Tables 14 and 15.

TABLE 13

| | | 1,4-difluoro-1,1,4,4- |
|---|---|---|
| Silicon precursor | | tetra(dimethlylamino)-1,4-disilabutane |
| Method of depositing | | Atomic layer deposition (ALD) |
| silicon oxide film | | |
| Substrate temperature | | 630 |
| (° C.) | | |
| Silicon | Heating | 80, 100 |
| precursor | temperature | |
| | (° C.) | |
| | Injection | 5, 10, 20 |
| | time (sec) | |
| Purge gas | Flow rate | 1000 |
| | (sccm) | |
| | Time (sec) | 10 |
| Reaction gas | Oxygen flow | 800, 4000 |
| | rate (sccm) | |
| | Hydrogen | 5, 10, 20 |
| | flow rate | |
| | (sccm) | |
| | Time (sec) | 2.5, 5, 10 |
| Purge gas | Flow rate | 1000 |
| | (sccm) | |
| | Time (sec) | 10 |
| Number of | Cycle | 200 |
| deposition | | |

TABLE 14

| | | Silicon | | | | |
|---|---|---|---|---|---|---|
| | | precursor | Silicon | | | |
| | Substrate | heating | precursor | Film | Growth | |
| Deposition | temperature | temperature | injection | thickness | rate | Refractive |
| method | (° C.) | (° C.) | time (sec) | [Å] | [Å/min] | index |
| ALD | 630 | 80 | 5 | 31 | 0.10 | 1.75 |
| | | 90 | 5 | 37 | 0.12 | 2.18 |
| | | 100 | 5 | 55 | 0.18 | 2.16 |
| | | 100 | 10 | 77 | 0.26 | 2.14 |
| | | 100 | 20 | 150 | 0.50 | 1.80 |

TABLE 15

| | | Oxygen | | Reaction | | |
|---|---|---|---|---|---|---|
| | Substrate | flow | Hydrogen | gas | Growth | |
| Deposition | temperature | rate | flow rate | injection | rate | Refractive |
| method | (° C.) | (sccm) | (sccm) | time (sec) | [Å/min] | index |
| ALD | 630 | 4000 | — | 2.5 | 0.39 | 2.09 |
| | | 4000 | — | 5 | 0.50 | 1.80 |
| | | 4000 | — | 10 | 0.42 | 2.08 |
| | | 800 | 20 | 5 | 0.53 | 2.85 |
| | | 4000 | 5 | 5 | 0.93 | 1.97 |
| | | 4000 | 20 | 5 | 1.01 | 1.75 |

The atom-specific content values of the silicon oxide film deposited under 630° C. conditions were analyzed using X-ray photoelectron spectrometer and are summarized in the following Table 16. As a result, C, N, and F compositions other than the SiOₓ thin film were confirmed.

TABLE 16

| | Oxygen | | Reaction | | | | | |
|---|---|---|---|---|---|---|---|---|
| Substrate | flow | Hydrogen | gas | | | | | |
| temperature | rate | flow rate | injection | Composition of film (at %) | | | | |
| (° C.) | (sccm) | (sccm) | time (sec) | C | N | O | Si | F |
| 630 | 4000 | — | 2.5 | 15.9 | 16.5 | 25.4 | 37.7 | 4.5 |
| | 4000 | — | 5 | 14.8 | 16.8 | 26.8 | 37.4 | 4.2 |
| | 4000 | — | 10 | 11.6 | 15.8 | 31.1 | 37.8 | 3.7 |
| | 800 | 20 | 5 | 19.7 | 17.4 | 22.5 | 35.0 | 5.3 |
| | 4000 | 5 | 5 | 19.0 | 17.2 | 23.9 | 34.4 | 5.5 |
| | 4000 | 20 | 5 | 16.4 | 16.2 | 27.6 | 35.0 | 4.7 |

The silicon compound according to an exemplary embodiment of the present invention has excellent thermal stability, allows deposition of a thin film with a high thin film deposition rate even under low temperature conditions, and allows production of a high-quality silicon-containing thin film with high purity by a simple production process.

In addition, since the silicon-containing thin film produced from the silicon compound according to an exemplary embodiment has both excellent chemical and thermal stability and also has very low dielectric constant, it is expected to be usefully applied as an insulating film of a semiconductor device, in particular, a spacer of a semiconductor miniaturization process.

Hereinabove, although the present invention has been described by specific matters, examples, and comparative examples, they have been provided only for assisting in the entire understanding of the present invention. Therefore, the present invention is not limited to the above examples. Various modifications and changes may be made by those skilled in the art to which the present invention pertains from this description.

Therefore, the spirit of the present invention should not be limited to the above-described exemplary embodiments, and the following claims as well as all modifications equal or equivalent to the claims are intended to fall within the scope and spirit of the invention.

What is claimed is:

1. A silicon compound represented by the following Chemical Formula 1: 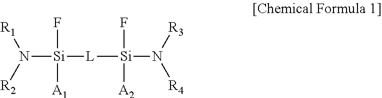
wherein:
A₁ and A₂ are, independently of each other, hydrogen, fluoro, C1-C7 alkyl, or —N (R₁₁) (R₁₂);
L is C1-C7 alkylene; and
R₁ to R₄, R₁₁, and R₁₂ are independently of one another C1-C7.

2. The silicon compound of claim 1, wherein:
A₁ and A₂ are, independently of each other, hydrogen, fluoro, C1-C4 alkyl, or N (R₁₁) (R₁₂);
L is C1-C4 alkylene; and
R₁ to R₄, R₁₁, and R₁₂ are, independently of one another, C1-C4 alkyl.

3. The silicon compound of claim 1, wherein the silicon compound is represented by the following Chemical Formula 1-1 or Chemical Formula 1-2: 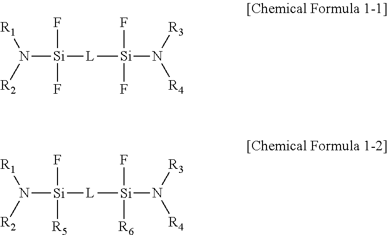
wherein:
L is C1-C7 alkylene;
R₁ to R₄ are, independently of one another, C1-C7 alkyl;
R₅ and R₆ are, independently of each other, hydrogen, C1-C7 alkyl, or —N (R₁₁) (R₁₂); and
R₁₁ and R₁₂ are, independently of each other, C1-C7alkyl.

4. The silicon compound of claim 3, wherein:
L is C1-C4 alkylene;
R₁ to R₄ are, independently of one another, C1-C4 alkyl;
R₅ and R₆ are, independently of each other, C1-C4 alkyl or —N (R₁₁) (R₁₂); and
R₁₁ and R₁₂ are, independently of each other, C1-C4 alkyl.

5. The silicon compound of claim 1, wherein the silicon compound is selected from the group consisting of the following structures:

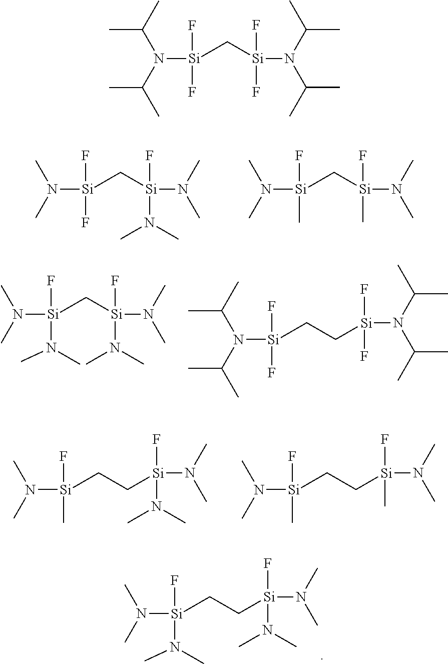

6. A method of producing a silicon compound, the method comprising:
reacting a compound of the following Chemical Formula 2 with compounds of the following Chemical Formulae 11 and 12 to produce a compound of the following Chemical Formula 3; and
reacting the compound of Chemical Formula 3 with a fluorine source to produce a silicon compound of the following Chemical Formula 1-1: 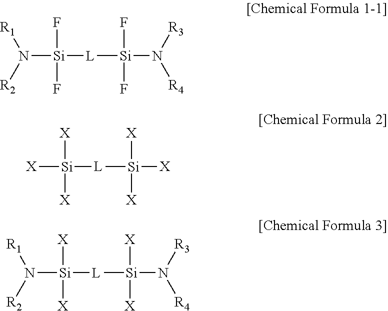
[Chemical Formula 11]
(R₁) (R₂) NH
[Chemical Formula 12]
(R₃) (R₄) NH
wherein:
X is Cl or Br; and
R₁ to R₄ are, independently of one another, C1-C7 alkyl.

7. A method of producing a silicon compound, the method comprising:
reacting a compound of the following Chemical Formula 2 with a fluorine source to produce a compound of the following Chemical Formula 4; and
reacting the compound of the following Chemical Formula 4 with compounds of the following Chemical Formulae 11 and 12 to produce a silicon compound of the following Chemical Formula 1-1: 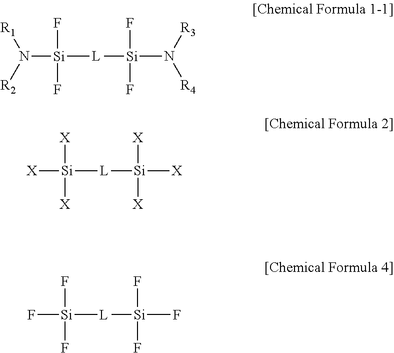
[Chemical Formula 11]
(R₁) (R₂) NH
[Chemical Formula 12]
(R₃) (R₄) NH
wherein:
X is Cl or Br; and
R₁ to R₄ are, independently of one another, C1-C7 alkyl.

8. A composition for depositing a silicon-containing thin film comprising the silicon compound of claim 1.

9. A method of producing a silicon-containing thin film, using the silicon compound of claim 1 or a composition for depositing the silicon-containing thin film including the silicon compound of claim 1.

10. The method of claim 9, wherein the silicon-containing thin film is a fluorine and silicon-containing thin film.

11. The method of claim 10, wherein the fluorine and silicon-containing thin film comprises fluorine in an amount of 0.5 at % or more.
